(19) United States
(12) Patent Application Publication
(10) Pub. No.: US 2012/0075221 A1
(43) Pub. Date: Mar. 29, 2012

(54) TOUCHSCREEN PANEL INPUT DEVICE MANUFACTURING METHOD, PIEZOELECTRIC ELEMENT AND TOUCHSCREEN PANEL INPUT DEVICE

(75) Inventor: Yoshiaki YASUDA, Yokohama-shi (JP)

(73) Assignee: STANLEY ELECTRIC CO., LTD., Tokyo (JP)

(21) Appl. No.: 13/242,260

(22) Filed: Sep. 23, 2011

(30) Foreign Application Priority Data
Sep. 27, 2010 (JP) 2010-214944

(51) Int. Cl. G06F 3/041; B32B 38/10; B32B 37/14; H01L 41/047; B32B 37/02

(52) U.S. Cl. 345/173; 310/366; 156/249

(57) ABSTRACT

A touchscreen panel input device is manufactured by forming a first adhesion layer and a second adhesion layer on a growth substrate, removing only the second adhesion layer from a selected region by irradiating laser, forming a growth base layer on the selected region where the second adhesion layer is removed and on the second adhesion layer and an oxide thin film having piezoelectricity on the growth base layer, transferring the oxide thin film layer on the selected region to a second substrate having first transparent electrodes by peeling-off, and adhering the second substrate to a third substrate having second transparent electrodes by placing the transferred oxide thin film layer between them. The touchscreen panel input device detects a pushing pressure in addition to a touch position with proving a tactile feedback.

This application is based on Japanese Patent Application ²⁰¹⁰-214944, filed on Sep. 27, 2010, the entire contents of which are incorporated herein by reference.

### BACKGROUND OF THE INVENTION

A) Field of the Invention

This invention relates to a method for manufacturing a touchscreen panel input device and to a piezoelectric element and a touchscreen panel input device manufactured by the method.

B) Description of the Related Art

Conventionally as an input method for a touchscreen panel, a resistive-type, a capacitive-type, a surface acoustic wave type, and an infrared scanning type have been known.

A resistive touchscreen panel consists of a pair of facing substrates, that is, a flexible upper substrate which is an input panel surface and a lower substrate which faces the upper substrate. Inside each substrate is coated with a transparent conductive film, and the transparent conductive films are facing each other with a predetermined gap not to contact with each other. A potential distribution is formed by using a lower transparent electrode film, and an operating position is detected by contact of electrodes when a user pushes the input panel surface with a finger or a stylus. In case of using a resistive touchscreen panel, transmittance of the panel is decreased by two transparent electrode layers. Moreover, two transparent electrodes are contacted at the time of input operation to detect a position; therefore, it tends to be damaged by being worn down, and there is a problem in durability because the transparent conductive film must be deformed. Furthermore, it is difficult to support multi-touch detection.

Similar to the resistive-type, a capacitive-type touchscreen panel detects a contact position from changes in capacitance by contact of a finger to an input panel coated with a transparent conductive film. Differences from the resistive-type are that only one substrate coated with a transparent conductive film is necessary and that multi-touch detection can be supported. The capacitive-type touchscreen panel detects changes in capacitance when a finger contacts with the panel; therefore, input tools such as a pen, a stylus, etc. other than a finger cannot be used.

A surface acoustic wave type and an infrared scanning type touchscreen panels detect a contact position by scanning a transparent panel with a surface acoustic wave or infrared ray. These types of touchscreen panels need no coating of transparent conductive film, but it is necessary to be equipped with a transmitter and a receiver of ultrasonic or infrared ray. Structures of the surface acoustic wave type and the infrared scanning type touchscreen panels tend to be complicated, and it is difficult to support a multi-touch detection.

Moreover, none of the above types of touchscreen panels can detect a pushing force of an input operation of a user. Those touchscreen panels just detect an input position on a panel but not a pushing pressure; therefore, it cannot be judged whether a user touches the position intentionally or unintentionally.

Furthermore, those touchscreen panels cannot feedback the input operation directly to the user. Notification may be possible by displaying confirmation message of the input operation on a display unit or by sound. In that case, the user needs to see the display device to confirm the input operation or the user may be anxious about whether or not the input operation is successfully completed because sometimes those kinds of indirect feedback takes time to reach the user. Therefore, as a result, the input operation by using those touchscreen panels may take time.

Regarding to detection of pushing pressures, Japanese Laid-Open Patent No. 2006-163619 (hereinafter called the Patent Document 1) discloses detection of pushing pressures by using an electric paper which is equipped with a piezoelectric element. Moreover, Japanese Laid-Open Patent No. 2004-125571 (hereinafter called the Patent Document 2) discloses detection of pushing pressures by using a sensor having a transparent piezoelectric crystal and transparent electrodes arranged on both sides of the transparent piezoelectric crystal. Furthermore, Japanese Laid-Open Patent No. 2010-26938 (hereinafter called the Patent Document 3) and Japanese Laid-Open Patent No. 2010-108490 (hereinafter called the Patent Document 4) discloses touchscreen panels which can detect pushing pressures by arranging transparent electrode patterns on both sides of transparent piezoelectric polymer films.

Regarding to input feedback, Japanese Laid-Open Patent No. 2003-288158 (hereinafter called the Patent Document 5) discloses a touchscreen panel display device which provides a tactile feedback to a fingertip of an operator of the device. The device provides a tactile feedback to a fingertip of the operator by oscillating a touchscreen panel to which the fingertip contacts in a direction perpendicular to a panel surface.

A touchscreen panel is positioned in front of a display device and so high transmittance is required for improving visibility of display by the display device. The touchscreen panels according to the Patent Documents 3 and 4 are formed of sheets of polyvinylidene difluouride (PVDF), which is piezoelectric polymer; therefore, the transmittance is high and pushing pressures can be detected at high precision. However, performance of generating the oscillation for the tactile feedback is low because polymer piezoelectric material is used.

On the other hand, the Patent Document 5 discloses that an element formed of laminated piezoelectric ceramics is used for both detecting pushing pressures and generating the oscillation for the tactile feedback. However, the element has no transmittance and so it must be positioned in non-display area in a periphery of a display area of a touchscreen panel. Therefore, the element cannot detect a touch input of a user directly but detects it indirectly via a touchscreen panel part, a mechanism and control circuit for detecting an input position become complicated, and it is impossible to perform position detection accurately or easily.

Moreover, it is difficult to detect a multi-touch input by a piezoelectric element alone and so detections of position and multi-touch have to depend on the capacitive-type or the resistive-type. The oscillation for the tactile feedback can be provided to a touchscreen panel as a whole but not locally to an input position. Whole touchscreen panel is oscillated even when the multi-touch detection, it is not sufficient for a tactile feedback function.

Furthermore, in case of detecting a position where a user pushes a panel from a voltage signal by deformation of a laminated piezoelectric actuator, a piezoelectric element keeps a deformed state depending on a pushing pressure when the user pushes the panel. If the pushing pressure is too strong, the laminated piezoelectric element may be damaged by the deformation because ceramics material forming the laminated piezoelectric element is fragile material.

### SUMMARY OF THE INVENTION

It is an object of the present invention to provide a method for manufacturing a touchscreen panel input device with high transmittance which can detect strength of a pushing pressure of a touch input in addition to detecting a touch position and provide a tactile feedback by generating oscillation locally at the touch position.

It is another object of the present invention to provide a touchscreen panel input device with high transmittance which can detect strength of a pushing pressure of a touch input in addition to detecting a touch position and provide a tactile feedback by generating oscillation locally at the touch position.

According to one aspect of the present invention, there is provided a method for manufacturing a touchscreen panel input device, comprising the steps of: (a) preparing a growth substrate, a second substrate on which a first transparent electrode layer is formed and a third substrate on which a second transparent electrode layer is formed; (b) forming a first adhesion layer on the growth substrate; (c) forming a second adhesion layer on the first adhesion layer; (d) removing only the second adhesion layer from a selected region by irradiating laser on a surface of the second adhesion layer in the selected region; (e) forming a growth base layer on the selected region where the second adhesion layer is removed and on the second adhesion layer; (f) forming an oxide thin film having piezoelectricity on the growth base layer; (g) adhering the growth substrate on which the oxide thin film layer is grown and the second substrate; (h) transferring the oxide thin film layer on the selected region where the second adhesion layer is removed to the second substrate by peeling-off the oxide thin film layer at an interface between the first adhesion layer and the growth base layer; and (i) adhering the second substrate to the third substrate by placing the transferred oxide thin film layer between the second substrate and the third substrate.

According to another aspect of the present invention, there is provided a piezoelectric element, comprising: a first transparent substrate; a first transparent electrode layer formed on the first transparent substrate; a second transparent substrate; a second transparent electrode layer formed on the second transparent substrate; and transparent piezoelectric oxide thin films placed between the first transparent electrode layer and the second transparent electrode layer, wherein at least one of the first transparent electrode layer and the second transparent electrode layer consists of a plurality of transparent electrodes, the first transparent electrode layer and the second transparent electrode layer are overlapped in a plurality of different regions, and each of the piezoelectric oxide thin films is formed in each of the region independently from each another.

According to still another aspect of the present invention, there is provided a touchscreen panel input device, comprising: a piezoelectric element comprising a first transparent electrode layer formed on the first transparent substrate, a second transparent substrate, a second transparent electrode layer formed on the second transparent substrate, and transparent piezoelectric oxide thin films placed between the first transparent electrode layer and the second transparent electrode layer; and a controller that detects a position in accordance with a voltage output from the piezoelectric oxide thin film and supplies a driving signal to the piezoelectric oxide thin film, wherein at least one of the first transparent electrode layer and the second transparent electrode layer consists of a plurality of transparent electrodes, the first transparent electrode layer and the second transparent electrode layer are overlapped in a plurality of different regions, and each of the piezoelectric oxide thin films is formed in each of the region independently from each another.

According to the present invention, a method for manufacturing a touchscreen panel input device with high transmittance which can detect strength of a pushing pressure of a touch input in addition to detecting a touch position and provide a tactile feedback by generating oscillation locally at the touch position can be provided.

According to the present invention, a touchscreen panel input device with high transmittance which can detect strength of a pushing pressure of a touch input in addition to detecting a touch position and provide a tactile feedback by generating oscillation locally at the touch position can be provided.

### BRIEF DESCRIPTION OF THE DRAWINGS

FIG. 1 is a schematic plan view of a touchscreen panel input unit 10 consisting of piezoelectric PZT thin film patterns according to an embodiment of the present invention.

FIG. 2 is a schematic cross sectional view showing an arrangement of transparent electrodes for each PZT thin film pattern 3 according to the embodiment of the present invention.

FIG. 3 is a schematic cross sectional view showing a structure of a touchscreen panel 100 equipped with the touchscreen panel input unit 10 according to the embodiment of the present invention.

FIG. 4 is a graph showing changes in input touch pressures and piezoelectric responses of the PZT film pattern 3.

FIG. 5 is a graph for explaining a control of locally generating oscillation for a tactile feedback.

FIG. 6 is a schematic cross sectional view for explaining a manufacturing method of the touchscreen panel input unit 10 according to the embodiment of the present invention.

### DESCRIPTION OF THE PREFERRED EMBODIMENTS

It has been well-known that lead perovskite oxide such as lead zirconate titanate (PZT) has high piezoelectricity. Comparing to polyvinylidene difluouride (PVDF), which is one of piezoelectric polymers, the PZT has piezoelectric constant (d31)=110 pm/V and electromechanical coupling factors (k)=0.6-0.8, which are performance indexes of electromechanical conversion, whereas the PVDF has lower indexes, that is, d31=20 pm/V and k=0.1. Therefore, it is understood that the lead perovskite oxide is more preferable for being used as an actuator than the piezoelectric polymer. However, the lead perovskite oxide has been used in an application as bulk ceramics but not in a sheet-type application or an application requiring transmittance.

Recently it becomes possible to form a thin film of the lead perovskite oxide which has similar piezoelectricity to bulk ceramics by solution coating, sputtering and ion-plating. The PZT thin film with a film thickness of 10-50 μm has 80% or more transmittance in a visible light range, and lead lanthanum zirconate titanate (PLZT) has 90% or more transmittance in a visible light range. The thin film of the perovskite oxide such as PZT, PLZT, etc. can be formed only on a heat resistance substrate because a thin film growth temperature is as high as 500 degrees Celsius or more.

A silicon wafer has been commonly used as substrate material for growing the perovskite oxide, and besides stainless steel, magnesium oxide single crystals, quartz, etc. have been used. Moreover, the perovskite oxide cannot be grown directly on a glass substrate; therefore, PVDF polymer, which has low piezoelectricity, has been selected as piezoelectric material arranged in a display region of a touchscreen panel.

The inventor of the present invention came up with a novel touchscreen panel input device having a piezoelectric thin film array as a basic structure which has high transmittance and high piezoelectricity by forming a perovskite oxide thin film formed of PZT, etc. having high piezoelectricity on a growth substrate and transferring the film on a touchscreen panel glass with desired patterns by peeling-off transfer.

Many cases of researches and developments have been reported regarding to a lower electrode structure using a PZT film and an adhesion layer which adheres the film with a substrate in a filed of ferroelectric capacitors. In those cases, it is the most common to form an adhesion layer formed of Ti under a lower electrode formed of Pt. That is because oxide (TiOₓ) is formed at an interface between the adhesion layer and a silicon thermal oxide film (SiO₂) on a surface of a Si substrate, a part of it is exposed on a surface of Pt electrode layer by solid phase diffusion, and that contributes to formation of an initial core and adhesion at a time of PZT film formation. On the other hand, there are many cases wherein the TiO₂, which is oxide of Ti, is formed under a Pt lower electrode.

Moreover, a lower electrode structure consisting of a three-layer structure of Pt/Ti/TiO₂ has been suggested as a combination of the merits of the above two structures.

In the embodiment of the present invention, a Ti layer of a three-layer structure of Pt/Ti/TiO₂ is partially removed by abrasion by laser irradiation, and thereafter peel-off transfer patterns as latent images are formed before PZT film formation by forming a Pt electrode layer on the partially removed Ti layer. Because whole surface of a substrate is covered by the Pt electrode layer at the time of PZT film formation, patterns of adhesion of the PZT film and the lower electrode with the substrate can be formed in accordance with the patterns of the Ti adhesion layer formed as latent images without affecting a growth of the PZT film having a perovskite crystal structure.

Adhesion of a pattern processed part (where the Ti adhesion layer is removed) is lowered compared to a non-processed part where the Ti adhesion layer is not removed); therefore, by performing an ultrasonic process, heat shock process, etc., the pattern processed parts are selectively peeled-off at a Pt/TiO₂ interface. That is, peel-off transfer of a PZT thin film pattern array can be realized efficiently by a self-lift-off effect. However, Pt is not transparent so that it has to be removed afterward.

By adhering a protection film sheet which becomes a touch surface of a touchscreen panel before peeling-off the PZT thin film, only the PZT film can be peel-off-transferred to the film sheet. Thereafter the film sheet to which a pattern array of the PZT thin film is transferred is adhered to a touchscreen panel glass substrate, and a touchscreen panel input device on which dispersed patterns of the piezoelectric PZT films are formed can be formed. Moreover, electric connections of PZT film patterns are done by transparent electrode patterns formed on a touchscreen panel glass in advance.

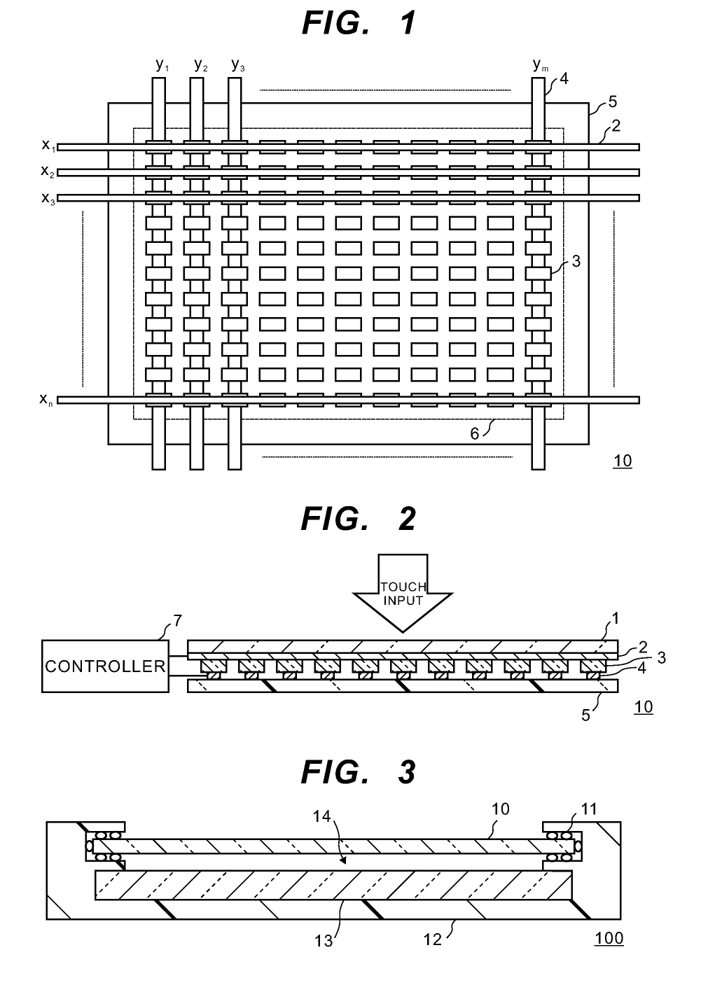

FIG. 1 is a schematic plan view of a touchscreen panel input unit 10 consisting of piezoelectric PZT thin film patterns according to an embodiment of the present invention. The drawing shows a state wherein the most upper layer, a transparent protection film sheet 1 (FIG. 2), is omitted. FIG. 2 is a schematic cross sectional view showing an arrangement of transparent electrodes for each PZT thin film pattern 3 according to the embodiment of the present invention.

PZT thin film patterns 3 are formed in a plurality of rows (n rows) and columns (m columns) in a display area on a touchscreen panel glass 5 which is the lowest layer. Each PZT thin film pattern 3 measures several milli-meters in consideration of a size of human fingertip. For example, in this embodiment, each PZT thin film pattern 3 measures 5 mm wide by 3 mm high. Moreover, a thickness of each PZT thin film pattern 3 preferably measures about 10-50 μm in consideration of a balance of a piezoelectric output and transmittance.

A plurality rows of x-direction transparent electrodes 2 (x₁-xₙ) are formed on a transparent protection film sheet 1 composing a touch surface of a touchscreen panel in correspondence with the rows of the PZT thin film patterns 3. Moreover, a plurality columns of y-direction transparent electrodes 4 (y₁-yₘ) are formed on a touchscreen panel glass 5 in correspondence with the columns of the PZT thin film patterns 3. The touchscreen panel input device 10 is formed by overlapping the transparent protection film sheet 1 and the touchscreen panel glass 5 with placing the PZT thin film patterns 3 between the x-direction transparent electrodes 2 and the y-direction transparent electrodes 4. In this embodiment, the x-direction transparent electrodes 2 and the y-direction transparent electrodes 4 function as electrode wirings for both touch detection and oscillation.

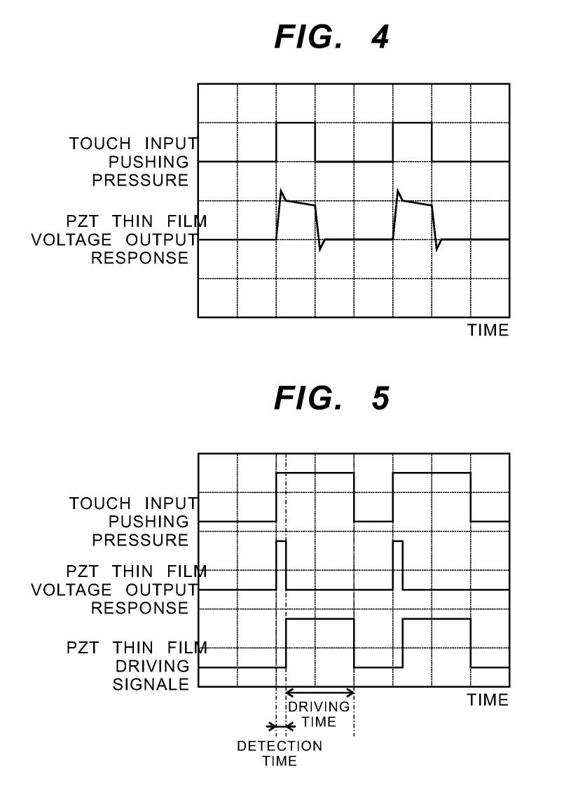

The x-direction transparent electrodes 2 and the y-direction transparent electrodes 4 are electrically connected to a controller (detecting/driving circuit) 7. The controller 7, as later described with reference to FIG. 4 and FIG. 5, detects a touch position and a pushing pressure of a touch by a user in accordance with a piezoelectric response from the PZT film pattern 3 and supplies a driving signal to the PZT film pattern which detected the touch to drive the PZT film pattern 3 to generate a local oscillation for a tactile feedback.

FIG. 3 is a schematic cross sectional view showing a structure of a touchscreen panel 100 equipped with the touchscreen panel input unit 10 according to the embodiment of the present invention. Above a display unit 13 such as a liquid crystal display (LCD), etc., a touchscreen panel input device 10 shown in FIG. 1 and FIG. 2 is placed inside a device body 12 in parallel to a display screen of the display unit with a space 14 via a dumper 11 such as rubber or gel for preventing the oscillation for a tactile feedback from transmitting to the display unit 13. A thickness of the space 14 is, for example, about 0.5 mm, and a thickness of the touchscreen panel input device 10 is, for example, about 0.5-0.7 mm.

By using PZT thin film patterns 3, strength of an input touch (pushing) pressure can be detected in addition to an input touch position while keeping high transmittance. Moreover, by arranging a multiplicity of the PZT thin film patterns 3 in a plurality of rows and columns instead of having one PZT thin film covering a whole surface, a tactile feedback can be provided to a user by locally piezoelectric-oscillating an input position.

Below explains a principle of touchscreen panel detection using the PZT piezoelectric thin film patterns 3 and a mechanism of a tactile feedback by local oscillation.

FIG. 4 is a graph showing changes in input touch pressures and piezoelectric responses of the PZT film pattern 3.

Approximately in proportion to strength of pushing pressures when a user touches for an input operation shown on the upper part of the graph, piezoelectric responses shown on the lower part of the graph are output from the PZT film pattern 3.

A position of the PZT film pattern 3 which the user pushes on a display region 6 of the touchscreen panel input device 10 is detected by a commonly used signal reading method for simple matrix wiring. That is, existence of output voltage is measured by scanning x-direction and y-direction scanning lines (the transparent electrodes 2 and 4) at a frequency (scanning speed) of several kHz. The position (input touch position) is determined as (x, y) coordinates by judging a scanning line number (x₁-xₙ) in the controller 7 (FIG. 2) in the x-direction and a scanning line number (y₁-yₘ) in the controller 7 in the y-direction.

Even in case of multi-touch, because the scanning speed is far faster than a movement of a human finger, multiple touch positions can be identified by processing detected voltage signals by the controller 7. Unlike the resistive-type and capacitive-type touchscreen, output voltages from the piezoelectric thin film are approximately in proportion to pushing pressures, and so a pushing pressure for each input position can be detected in accordance with the output voltage.

FIG. 5 is a graph for explaining a control of locally generating oscillation for a tactile feedback. Pushing pressures when a user touches for input are shown on the upper part of the graph.

In order to simplify the structure of the touchscreen panel input device 10, the electrode wirings in the embodiment are used for both touch detection and oscillation driving. Therefore, as shown in the middle part of the graph, the controller 7 (FIG. 2) measures a voltage from the PZT thin film pattern 3 in a short time by setting the scanning frequency for the touch detection to high, and, as shown on the lower part of the graph, supplies an oscillation driving signal to the PZT thin film pattern 3 which has detected the voltage (touch) at a timing just after the detection of the voltage (touch).

That is, the crosstalk of both signals is prevented by dividing a scanning frame of touch input into detecting time and driving time. The response speed of the piezoelectric is far faster than a time necessary for a human to perceive the oscillation, and so it is possible to detect a touch position and strength of touch pressure of touch input with a finger of a user and generate the local oscillation by driving the PZT thin film pattern 3 at the touch position while a finger of the user is still contacting with the panel immediately after the detection.

Because a thickness of each PZT thin film pattern 3 is thin (for example, 10-50 μm) comparing to its two-dimensional size (for example, 5 mm by 3 mm), it oscillates along a plane in parallel to the panel surface more than in a film thickness direction perpendicular to the panel thickness surface and so it is possible to oscillate a local area of a movable panel unit by an actuator formed of a thin film fragment having small driving power. Moreover, the oscillation according to the embodiment does not oscillate the whole surface of the panel; therefore, it is possible to give a different feedback to each finger at the time of multi-touch input. Therefore, it is possible to provide sense of clicking for each key of a virtual keyboard, which is difficult to provide in the prior art.

Although a plurality rows and columns of patterns are formed in the above-described embodiment, there is no need for making rules for arrangement or sizes of thin film patterns. Any modification can be made to the piezoelectric element as far as at least one of electrode layers consists of a plurality of electrodes, both electrode layers are overlapped in a plurality of different regions, and each of the piezoelectric bodies (piezoelectric oxide thin films) is formed in each of the region independently from each another. The piezoelectric body exists independently from others in each region and so it is possible to control each without affecting others. For example, the arrangement and sizes of the overlapped regions can be determined in correspondence to keys of a virtual keyboard. However, it is preferable to arrange piezoelectric bodies in a plurality rows and columns as in the embodiment in terms of flexibility for serving various purposes depending on display screens. In any cases, the position detection and oscillation are performed by a combination of the upper and the lower electrodes.

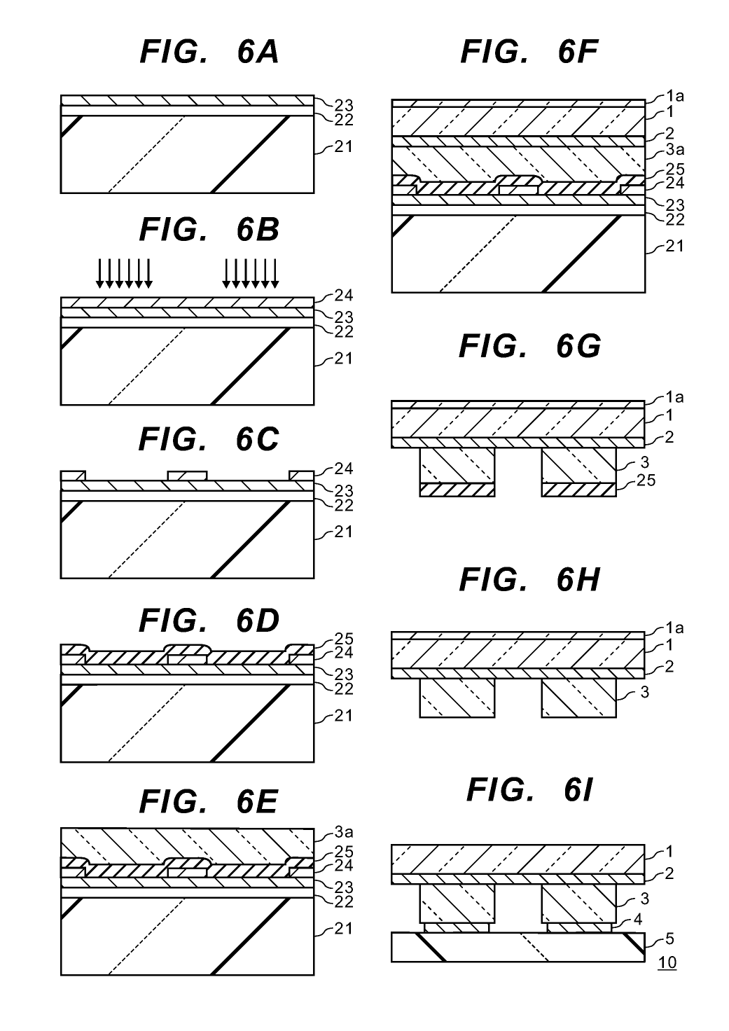

FIG. 6 is a schematic cross sectional view for explaining a manufacturing method of the touchscreen panel input unit 10 according to the embodiment of the present invention.

In this embodiment, a six-inch silicon (Si) wafer with a thickness of 650 μm is used as a substrate 21 for growing PZT films. In the embodiment, there is no limit for material of the substrate 21; however, it is preferable to use either one of a Si wafer and a SOI wafer.

As shown in FIG. 6A, at first a thermal oxide film 22 with a film thickness of 0.5 μm is formed on a surface of the Si wafer 21 by electric furnace heating, and thereafter a titanium oxide (TiO₂) thin film (first adhesion layer) 23 with a film thickness of 0.1 μm is formed on the thermal oxide film 22 by sputtering TiO₂ by a magnetron-sputter coater with a film forming pressure of 0.4 Pa, a substrate heating temperature of 300 degrees Celsius and RF power of 500 W. Moreover, the first adhesion layer 23 may be formed of ZrO₂, RuO₂ and IrO₂ besides TiO₂.

After forming the TiO₂ thin film 23, a Ti thin film (second adhesion layer) 24 with a film thickness of 0.02 μm is continuously formed by the same magnetron-sputter coater by sputtering Ti at a DC power of 1 Kw. Thereafter as shown in FIG. 6B, a high power focused laser beam is irradiated to a part of the Ti thin film 24 as shown in the drawing (bundles of arrows represent the laser beam). By that, the part of the Ti thin film 24 where the laser beam is irradiated evaporates and disappears by abrasion effect. As a result, as shown in FIG. 6C, patterns of the Ti thin film 24 are formed on the TiO₂ thin film 23. For example, a rectangle excimer laser (248 nm) having an energy of 300 mJ·² is irradiated to a Ti surface of the substrate 21 on which the Ti thin film has been already formed by a step and repeat method with a dimensional size of 5 mm by 3 mm for each region, and the Ti thin film 24 in each region is evaporated and eliminated by the abrasion. The dimensional size of each region becomes a size of each PZT thin film pattern 3. The positioning of irradiation region is executed by moving the substrate 21 on an X-Y stage with reference to an outline (an orientation flat, a notch, etc.) of the substrate 21. Moreover, spaces between the regions are set to 0.2 mm wide.

The laser used in the embodiment may be one of an excimer laser (XeF:351 nm, XeCI:308 nm, KrF:248 nm, KrCI:222 nm, ArF:193 nm, etc.) and a third harmonic (355 nm) of s Nd:YAG laser and a fourth harmonic (266 nm) of s Nd:YAG laser, and it is necessary to be high power with an optical output of several 100 mJ/cm².

Moreover, a shape and size of the laser beam is preferably changeable to various beam profiles such as a circle, a rectangle, a linear shapes, etc. in accordance with designs of the element. Generally the excimer laser is suitable for a larger beam size, and the Nd:YAG laser is suitable for smaller beam size. However, the beam profiles can be changed by a focus optical system and so there is no substantial difference between the above two types of lasers.

Furthermore, besides Ti, the second adhesion layer 24 may be formed of Zr, Ru, Ir, Au, Cu, Ni, etc.

Next, the substrate 21 is cleaned, and a platinum (Pt) thin film 25 as a growth base layer is formed by magnetron sputtering as shown in FIG. 6D. The patterns of the Ti thin films 24 become latent images, and the Pt thin film 25 covers the whole surface of the substrate 21. For example, Pt is sputtered by the magnetron-sputter coater at the DC power of 500 W to form the Pt thin film 25 with a film thickness of 0.15 μm. The film formation conditions are, for example, a pressure of 0.4 Pa and substrate heating temperature of 300 degrees Celsius.

Moreover, besides Pt, the growth base layer 25 may be formed of Ir, SrRuO₃, LaNiO₃ or a lamination of them.

Thereafter, as shown in FIG. 6D, a PZT thin film 3a made of Pb(ZrₓTi₁₋ₓ)O₃ (x=0.5) is grown by the arc discharged reactive ion plating (ADRIP) (refer to Japanese Laid-Open Patent No. 2001-234331, Japanese Laid-Open Patent No. 2002-177765, and Japanese Laid-Open Patent No. 2003-81694). The Pt thin film 25 is exposed on all surface of the substrate 21 at the time of film formation; therefore, the PZT thin film 3a with a good crystal quality grows. For example, the PZT film 3a with a film thickness of 3-20 μm is formed at a pressure of 0.1 Pa and a substrate temperature of 550 degrees Celsius.

Next, as shown in FIG. 6F, the (PZT thin film growth) substrate 21 on which the PZT thin film 3a has been grown is adhered to a protection film sheet 1 on which a transparent electrode pattern 2 has been grown. For example, the protection film sheet 1 is made of polyethylene terephthalate (PET) or the likes. In this embodiment, the PZT thin film growth substrate 21 is surface-activated by plasma cleaning and thereafter is adhered to the protection film sheet 1 having the transparent electrode layer whose surface has also been surface-activated by plasma cleaning (surface activated bonding). Moreover, the protection film sheet 1 is temporary adhered to and supported by a glass (or resin) substrate 1a in advance.

Thereafter the substrate 21 having thin film layers including the PZT thin film 3a is treated with an ultrasonic process or a heat-shock process. For example, the substrate 21 is soaked into a container holding isopropyl alcohol (IPA) solution and treated by the ultrasonic process at 1 kW for five minutes by putting the container into an ultrasonic cleaning tub. By that portions of the PZT thin film 3a with the Pt thin film 25 below the portions are peeled-off from Pt/TiO₂ interfaces in the regions where the Ti thin films 24, the adhesion layer, are removed (where the Ti thin films 24 are removed by the laser irradiation), and peel-off transfer patterns by self-lift-off of the PZT thin film 3a are formed on the protection film sheet 1 as shown in FIG. 6G.

Next, as shown in FIG. 6H, the Pt thin films 25 on the PZT thin film patterns 3 are removed by dry-etching, and the transparent piezoelectric PZT thin film patterns 3 are formed on the transparent electrode patterns 2 of the protection film sheet 1.

Then, as shown in FIG. 6I, the protection film sheet 1 on which the PZT thin film patterns 3 are formed is adhered to the touchscreen panel glass substrate 5 on which the transparent electrode patterns 4 are formed, and the support substrate 1a temporary adhered to the protection film sheet 1 is peeled-off. In this embodiment, the protection film sheet 1 on which the PZT thin film patterns 3 are formed is surface-activated by plasma cleaning and thereafter adhered to the touchscreen panel glass substrate 5 which is also surface-activated by the plasma cleaning and on which the transparent electrode patterns 4 are formed (surface activated bonding). The touchscreen panel input device 10 is fabricated by cutting the adhered substrates into a size of a display device and electrically connecting to the controller 7 (FIG. 2) by using flexible tapes or the likes.

Moreover, the silicon wafer 21 used for growing the PZT thin film can be re-used as a growth substrate for the PZT thin film by removing the remaining thin film layers by etching and polishing the uppermost surface. Therefore, cost of manufacturing can be reduced.

According to the embodiment of the present invention, the transparent electrode patterns of thin films with a thickness of several tens of milli-meters made of lead perovskite oxide (e.g., PZT, PLZT, etc.) having high performance as piezoelectric actuators are formed by adhering them to a touchscreen panel material as a group of patterns with a size of several milli-meters but not as one contiguous sheet of a thin film. Therefore, there can be provided a touchscreen panel input device that has high transmittance which can be arranged on a display region of a display device, is capable of detecting an input position and strength of a touch pressure by a touch of a user, and also has a tactile feedback function which can transmit sense of clicking and operating to the user by local oscillation of the input position.

Moreover, according to the embodiment of the present invention, for giving sense of touching to a fingertip of a user contacting a panel surface, a movable panel unit can locally oscillate along a plane in parallel to the panel surface more than in a film thickness direction perpendicular to the panel thickness surface. Therefore, it is possible to oscillate a local area of the movable panel unit by an actuator formed of a thin film fragment having small driving power, and the panel surface does not make the surrounding air oscillate. Therefore, the touchscreen panel display device which can provide tactile sense to a fingertip of an operating user can be easily miniaturized in a size, in a thickness and in a weight and is made to reduce power consumption and noises.

Although the silicon wafer is used for the growth substrate 21 for growing the PZT film in the above-described embodiment, a stainless-steel plate can be used. For example, it is possible to grow the latent image patterns of Ti thin films 24 and the PZT films on the stainless-steel plate with a thickness of 0.3 mm and a size of 350 mm by 250 mm by using the similar method as in the above-described embodiment (although the thermal oxide film formation process must be excluded). In case of using the stainless-steel plate, reuse of the plate is difficult because of an influence of heat history of the PZT film formation. However, stainless-steel plates are significantly cheaper than silicon wafers and so there is no problem in industrial applications.

Although the Pt thin film 25 is peeled-off by the ultrasonic process in the above described embodiment, it can be peeled-off by a heat-shock cycle. In this case, for example, the Pt thin film 25 can be peeled-off by repeating the heat shock cycle of 150 degrees Celsius environment and −40 degrees Celsius environment for several times.

Further, the PZT thin film pattern 3 may be buried by filling up its surroundings with silicone transparent resin, etc.

The present invention has been described in connection with the preferred embodiments. The invention is not limited only to the above embodiments. It is apparent that various modifications, improvements, combinations, and the like can be made by those skilled in the art.

What are claimed are:

1. A method for manufacturing a touchscreen panel input device, comprising the steps of:
(a) preparing a growth substrate, a second substrate on which a first transparent electrode layer is formed and a third substrate on which a second transparent electrode layer is formed;
(b) forming a first adhesion layer on the growth substrate;
(c) forming a second adhesion layer on the first adhesion layer;
(d) removing only the second adhesion layer from a selected region by irradiating laser on a surface of the second adhesion layer in the selected region;
(e) forming a growth base layer on the selected region where the second adhesion layer is removed and on the second adhesion layer;
(f) forming an oxide thin film having piezoelectricity on the growth base layer;
(g) adhering the growth substrate on which the oxide thin film layer is grown and the second substrate;
(h) transferring the oxide thin film layer on the selected region where the second adhesion layer is removed to the second substrate by peeling-off the oxide thin film layer at an interface between the first adhesion layer and the growth base layer; and
(i) adhering the second substrate to the third substrate by placing the transferred oxide thin film layer between the second substrate and the third substrate.

2. The method for manufacturing a touchscreen panel input device according to claim 1, wherein the piezoelectric oxide thin film is formed of one of a piezoelectric composition selected from piezoelectric oxide having a perovskite crystal structure, piezoelectric oxide having a layered perovskite crystal structure, non-lead perovskite-type piezoelectric oxide, and a single crystalline piezoelectric thin film.

3. The method for manufacturing a touchscreen panel input device according to claim 1, wherein the first adhesion layer is formed of at least one of TiO₂, ZrO₂, RuO₂, and IrO₂,
the second adhesion layer is formed of at least one of Ti, Zr, Ru, Ir, Au, Cu, and Ni, and
the growth base layer is formed of at least one or a lamination of Pt, Ir, SrRuO₃, and LaNiO₃.

4. A piezoelectric element, comprising:
a first transparent substrate;
a first transparent electrode layer formed on the first transparent substrate;
a second transparent substrate;
a second transparent electrode layer formed on the second transparent substrate; and
transparent piezoelectric oxide thin films placed between the first transparent electrode layer and the second transparent electrode layer,
wherein at least one of the first transparent electrode layer and the second transparent electrode layer consists of a plurality of transparent electrodes,
the first transparent electrode layer and the second transparent electrode layer are overlapped in a plurality of different regions, and
each of the piezoelectric oxide thin films is formed in each of the region independently from each another.

5. The piezoelectric element according to claim 4, wherein
the first transparent electrode layer consists of a plurality rows of transparent electrodes,
the second transparent electrode consists of a plurality columns of transparent electrodes, and
the piezoelectric oxide thin films are formed in a plurality of rows and columns.

6. A touchscreen panel input device, comprising:
a piezoelectric element comprising a first transparent electrode layer formed on the first transparent substrate, a second transparent substrate, a second transparent electrode layer formed on the second transparent substrate, and transparent piezoelectric oxide thin films placed between the first transparent electrode layer and the second transparent electrode layer; and
a controller that detects a position in accordance with a voltage output from the piezoelectric oxide thin film and supplies a driving signal to the piezoelectric oxide thin film, wherein
at least one of the first transparent electrode layer and the second transparent electrode layer consists of a plurality of transparent electrodes,
the first transparent electrode layer and the second transparent electrode layer are overlapped in a plurality of different regions, and
each of the piezoelectric oxide thin films is formed in each of the region independently from each another.
